(19) United States
(12) Patent Application Publication
(10) Pub. No.: US 2026/0039296 A1
(43) Pub. Date: Feb. 5, 2026

(54) SWITCH

(71) Applicant: STMICROELECTRONICS INTERNATIONAL N.V., Geneva (CH)

(72) Inventor: Laurent MOINDRON, Vernou sur Brenne (FR)

(21) Appl. No.: 19/271,946

(22) Filed: Jul. 17, 2025

(30) Foreign Application Priority Data
Jul. 30, 2024 (FR) FR2408444

(51) Int. Cl. H03K 17/693; H03K 17/725

(52) U.S. Cl. CPC H03K 17/693; H03K 17/725

(57) ABSTRACT

The present disclosure provides an electronic device for driving a switch. An example electronic device for driving a switch includes: a first d driving circuit of the switch referenced to the first terminal adapted receive an alternating potential, formed on a first substrate, and comprising a first diode whose cathode is connected to the first substrate; a second driving circuit referenced to the second terminal adapted to receive a reference potential, formed on a second substrate, and comprising a second diode whose cathode is connected to the second substrate; and an anode of the first diode is connected to the second driving circuit, and an anode of the second diode is connected to the first driving circuit.

### CROSS REFERENCE TO RELATED APPLICATION(S)

This application claims the priority benefit of French patent application number FR2408444, filed on Jul. 30, 2024, entitled “Commutateur”, which is hereby incorporated by reference to the maximum extent allowable by law.

### TECHNICAL FIELD

The present description relates generally to electronic systems and devices, and to the power supply of these electronic systems and devices using AC voltage. Particularly, the present description relates to a switch suitable for controlling the power supply of a load with an AC voltage.

### BACKGROUND

Using an AC voltage to power an electrotechnical or electronic device, called load, is very common. Indeed, residential electricity wiring provides an AC voltage.

There are existing control switches suitable for controlling the power supply of a load with an AC voltage. More particularly, such a switch is serially coupled to the load, and allows it to be connected or disconnected to a power supply providing a AC voltage.

It would be desirable to be able to improve, at least in part, some aspects of the known control switches.

### BRIEF SUMMARY

There is a need for electronic systems and devices reliably powered with an AC voltage.

There is a need for switches suitable for controlling the power supply with AC voltages for electronic systems and devices in a reliable way.

There is especially a need for double-throw voltage and current switches allowing the power supply of an electronic device to be controlled with an AC voltage in a reliable way.

One embodiment overcomes all or part of the drawbacks of known electronic systems and devices powered with an AC voltage.

Particularly, one embodiment overcomes all or part of the drawbacks of known switches suitable for controlling the power supply with AC voltage for an electronic system or device.

One embodiment provides a double-throw voltage and current switch.

One embodiment provides a double-throw switch comprising two thyristors arranged in antiparallel to each other, each controlled with its own driving circuit.

One embodiment provides an electronic device for driving a switch comprising:
a first terminal adapted to receive an alternating potential;
a second terminal adapted to receive a reference potential;
a first driving circuit of the switch referenced to the first terminal, formed on a first substrate, and comprising a first diode whose cathode region is connected to the first substrate;
a second driving circuit referenced to the second terminal formed on a second substrate different from the first substrate, and comprising a second diode whose cathode region is connected to the second substrate;
   wherein an anode region of the first diode is connected to the second driving circuit, and an anode region of the second diode is connected to the first driving circuit.

According to an embodiment, the first driving circuit comprises a first transistor for controlling the switch, and the anode region of the second diode is connected to a drain terminal of the first transistor.

According to an embodiment, the second driving circuit comprises a second transistor for controlling the switch, and the anode region of the first diode is connected to a drain terminal of the second transistor.

According to an embodiment, the first and second transistors are MOS type transistors.

According to an embodiment, the first and second diodes are parasitic diodes of third MOS type transistors.

According to an embodiment, the first and second diodes are substrate diodes of third transistors.

According to an embodiment, the first and second diodes are intrinsic diodes of the third transistors whose source terminals are connected to their substrate terminals.

According to an embodiment, the first and second diodes are diodes laterally isolated by deep isolation trenches.

According to an embodiment, the first driving circuit comprises a power supply circuit connected to the first terminal.

Another embodiment provides switch comprising:
a driving device previously described;
a first thyristor whose cathode is connected to the first terminal, and whose anode is connected to the second terminal and adapted to be driven by the first driving circuit; and
a second thyristor whose anode is connected to the first terminal, and whose cathode is connected to the second terminal and adapted to be driven by the second driving circuit.

According to an embodiment, the first transistor comprises a source terminal connected to the trigger of the first thyristor.

According to an embodiment, the second transistor comprises a source terminal connected to the trigger of the second thyristor.

Another embodiment provides an electronic device comprising a load adapted to receive an alternating voltage and a switch previously described, wherein a third terminal of the load is connected to the first terminal.

Another embodiment provides an electronic system comprising a device previously described and a power supply adapted to provide an alternating voltage.

Another embodiment provides a method of controlling a load supplied by a power supply adapted to supply an alternating voltage, in which the load is connected to the power supply by a switch, the switch comprising:
a first terminal adapted to receive an alternating potential;
a second terminal adapted to receive a reference potential;
a first thyristor whose cathode is connected to the first terminal, and whose anode is connected to the second terminal;
a first driving circuit of the switch referenced to the first terminal, formed on a first substrate, and comprising a first diode whose cathode region is connected to the first substrate;
a second driving circuit of the second thyristor referenced to the second terminal formed on a second substrate different from the first substrate, and comprising a second diode whose cathode region is connected to the second substrate;
   wherein an anode region of the first diode is connected to the second driving circuit, and an anode region of the second diode is connected to the first driving circuit.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 illustrates an electronic system comprising a switch according to one embodiment;

FIG. 2 illustrates in more detail an electronic system comprising a switch according to one embodiment; and

FIG. 3 illustrates a section view of a part of MOS transistor; and

FIG. 4 illustrates a section view of diode.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc, or to relative positional qualifiers, such as the terms “above”, “below”, “higher”, “lower”, etc, or to qualifiers of orientation, such as “horizontal”, “vertical”, etc, reference is made to the orientation shown in the figures.

Unless specified otherwise, the expressions “around”, “approximately”, “substantially” and “in the order of” signify within 10%, and preferably within 5%.

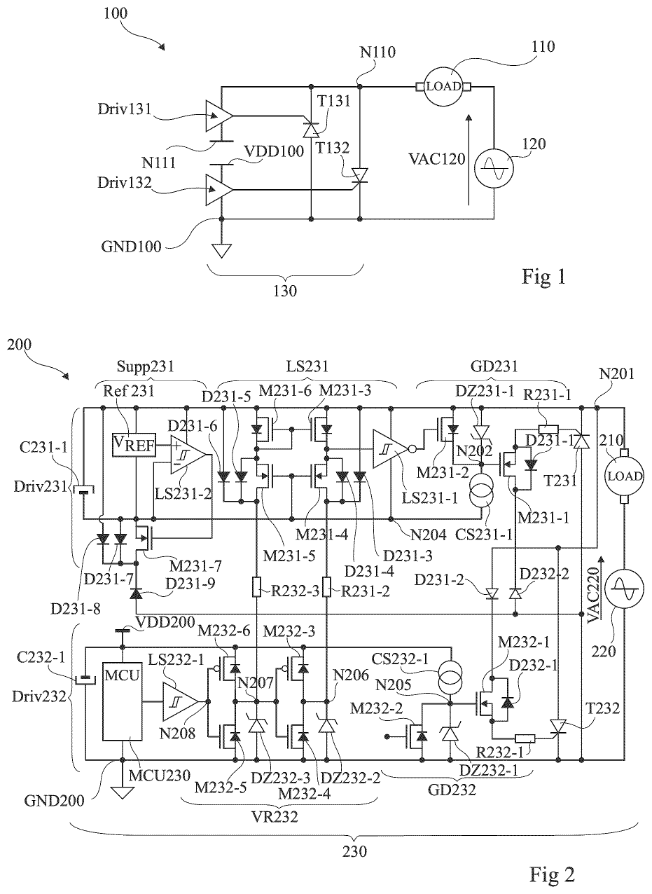

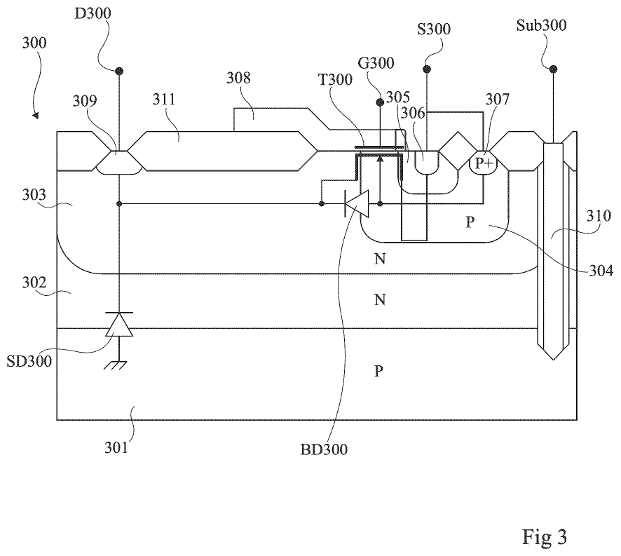

The embodiments hereafter described relate to powering with an AC voltage, such as a voltage provided by residential electricity wiring, also called power grid, electronic systems and devices. The embodiments concerned with the present disclosure relate more particularly to a switch suitable for controlling the power supply of an electrotechnical or electronic device. The switch of interest is a double-throw current or voltage switch comprising two thyristors arranged antiparallel to each other, and controlled each with its own driving circuit. The general diagram of such a switch, is described with reference to FIG. 1, and a specific example of this switch is described with reference to FIG. 2. Opposite to the other switches on the market, this switch has the advantage of having no issue of uncontrolled conduction at the time when the AC current sign changes. To this end, the driving circuits who's adapted to controlled the switch use spurious diodes cleverly disposed to provide against reverse polarities. This is described in detail with reference to FIGS. 2 and 3.

In addition, the embodiments hereafter described are especially suitable for use in the field of industrial electronic devices, such as industrial ovens (bakery oven, ovens dedicated to large cooking), industrial engines, particularly their starting circuits that may draw high intensity currents, solid state relays such as switches suitable for high voltages, e.g. voltages in the order of 400 V, and for high currents, e.g. currents driving higher than 1 A and can go up to a few tens Amperes.

In addition, more generally, the embodiments hereabove described are especially suitable for use in any type of industrial markets where is required powering the electronic devices with AC voltages. More particularly, such a switch could be intended to the industrial industry, for example in the green energy field, in the field of infrastructure electrification, of Internet of Things (IOT), and of smart home, where the power and energy consumption are key element.

FIG. 1 illustrates an embodiment of an electronic system 100 comprising an electronic device 110.

According to one embodiment, the electronic system 100 comprises a load 110 symbolizing the part of the electronic system 100 intended to be powered with a power supply 120. According to an example, the load 110 is an electrotechnical device. The system 100 further comprises one embodiment of a switch 130 suitable for controlling the current and voltage supply of the load 110 by power supply 120.

According to one embodiment, the power supply 120 is an AC voltage source suitable for providing an AC voltage VAC120 allowing the electronic device 110 to be powered.

To form the system 100, this different systems are mounted as follows. A first terminal of the power supply 120 is coupled, preferably connected, to a first terminal of the load 110. A second terminal of the power supply 120 is coupled, preferably connected, to a node GND100 constituting a reference node of the system 100, and providing a reference potential, e.g. ground. A second terminal of the load 110 is coupled, preferably connected, to a node N110. A first terminal of the switch 1130 is coupled, preferably connected, to a node N110, and a second terminal of the switch 130 is coupled, preferably connected, to the reference node GND100.

According to one embodiment, the switch 130 is a double-throw current and voltage switch. Switch 130 comprises two thyristors T131 and T132, and their driving circuits Driv131 and Driv132. The thyristors T131 and T132 are antiparallelly coupled between nodes N110 and GND100. More particularly, a cathode terminal of the thyristor T131 is coupled, preferably connected, to node N110, and an anode terminal of the thyristor T131 is coupled, preferably connected, to node GND100. A cathode terminal of the thyristor T132 is coupled, preferably connected, to node GND100, and an anode terminal of the thyristor T132 is coupled, preferably connected, to node N110.

The driving circuit Driv131 is intended to drive the thyristor T131. To this end, the driving circuit Driv131 comprises an output terminal coupled, preferably connected, to a gate terminal of the thyristor T131. The driving circuit Driv131 is referenced by the node N110, and is powered with a potential provided by a node N111.

The driving circuit Driv132 is intended to drive the thyristor T132. To this end, the driving circuit Driv132 comprises an output terminal coupled, preferably connected, to a gate terminal of the thyristor T132. The driving circuit Driv132 is powered by a node VDD100 providing a DC power voltage, and is referenced to a reference node GND100.

According to an embodiment, the driving circuits Driv131 and Driv132 are both integrated onto two different dies having different substrates, each substrate being referenced to a different reference potential. More particularly, the substrate of the driving circuit Driv131 is referenced to the node N111 which provides an alternating potential, and the substrate of the driving circuit Driv132 is referenced to the node GND100. According to an embodiment, the two dies on which the driving circuits Driv131 and Driv132 are integrated are then assembled into a unique packaging to form a single circuit which can be called a driving device. According to a variant, the two dies of driving circuits Driv131 and Driv132 and the two dies of thyristors T131 and T132 can be assembled in a unique packaging forming the switch 130.

The system 100 and particularly switch 130 of the device 110, has an improvement allowing it to avoid unintentional conduction issues at a time when the AC current sign changes in the load 110. Such issues are known in some switches, such as triacs. This improvement will be described in detail in reference to FIG. 1.

A method for controlling the power supply of a load within the system 100 is as follows. When the load 110 operates, and needs to be powered, the switch 130 is turned ON. To this end, the driving circuits Driv131 and Driv132 send a control current pulse to the thyristors T131 and T132. Thyristors T131 and T132 remain ON as long as a current flows through them. When the load 110 is out of operation, and does not need to be powered, the switch 130 is turned OFF. To this end, the thyristors T131 and T132 are turned OFF by sending them no control current pulse.

Thus, the embodiments described herein relate to a system of the type of system 100, a switch of the type of switch 130, and a driving device comprising driving circuits of the type of driving circuits Driv131 and Driv132. The embodiments described herein further relate to a method for controlling the power supply of a load.

FIG. 2 illustrates one embodiment of an electronic system 200 comprising a load 210 suitable for being powered with an electrical power supply 220, and the power supply is suitable for being controlled with one embodiment of a switch 230.

According to one embodiment, the load 210 is of the type of the load 110 described in reference to FIG. 1. Similarly, the power supply 220 is of the type of the power supply 120 described in reference to FIG. 1, and provides an AC power supply voltage VAC220. Lastly, the switch 230 is of the type of the switch 130 described in reference to FIG. 1.

The switch 230 comprises a first terminal coupled, preferably connected, to a node N201, in turn coupled, preferably connected, to a terminal of the load 210. The switch 230 further comprises a second terminal coupled, preferably connected, to a reference node GND200 of the system 200.

According to one embodiment, like the switch 130, the switch 230 is a double-throw current and voltage switch. The switch 230 comprises two thyristors T231 and T232, and their driving circuits Driv231 and Driv232. Thyristors T231 and T232 are antiparallelly coupled between nodes N201 and GND200. More particularly, a cathode terminal of the thyristor T231 is coupled, preferably connected, to node N201, and an anode terminal of the thyristor T231 is coupled, preferably connected, to node GND200. A cathode terminal of the thyristor T232 is coupled, preferably connected, to node GND200, and an anode terminal of the thyristor T232 is coupled, preferably connected, to node N201.

According to an embodiment, the driving circuits Driv231 and Driv232 are both integrated onto two different dies having different substrates, each substrate being referenced to a different reference potential. More particularly, the substrate of the driving circuit Driv231 is referenced to the node N201 which provides an alternating potential, and the substrate of the driving circuit Driv232 is referenced to the node GND200. According to an embodiment, the two dies on which the driving circuits Driv231 and Driv232 are integrated are then assembled into a unique packaging to form a single circuit which can be called a driving device. According to a variant, the two dies of driving circuits Driv231 and Driv232 and the two dies of thyristors T231 and T232 can be assembled in a unique packaging forming the switch 230.

The driving circuit Driv231 is intended to drive the thyristor 231. To this end, the driving circuit Driv231 comprises an output terminal coupled, preferably connected, to a gate terminal of the thyristor 231. The driving circuit Driv231 is supplied with the node N204 and is referenced to node N201.

The driving circuit Driv231 includes:
a circuit GD231 for controlling the gate of the thyristor 231;
a level shifter circuit LS231; and
a power supply circuit Supp231.

The circuit GD231 for controlling the gate of the thyristor 231 is a circuit allowing a control current pulse to be provided to the gate of the thyristor 231. In other words, an output of the circuit GD231 corresponds to the output of the driving circuit Driv231.

The circuit Driv231 comprises a metal-oxide-semiconductor field-effect transistor M231-1, or MOSFET transistor, or MOS transistor. According to one example, the transistor M231-1 is a N-channel MOS transistor, or N-type MOS transistor, or NMOS transistor. According to one alternative within the capabilities of those skilled in the art, the transistor M231-1 could be a P-channel MOS transistor, or P-type MOS transistor, or PMOS transistor. A source terminal of the transistor M231-1 is coupled to the gate of thyristor T231, for example via a resistor R231-1. A drain terminal of the transistor M231-1 is coupled to the reference node GND200. A parasitic diodes of the transistor M231-1 is shown in FIG. 2. This parasitic diode is an intrinsic diode D231-1, also called body diode, the anode of which is coupled, preferably connected, to the source terminal of the transistor M231-1, and the cathode of which is coupled, preferably connected, to the drain terminal of the transistor M231-1. According to an embodiment, the circuit GD231 further comprises a diode D231-2 formed in and on the substrate on which the circuit Driv231 is formed. According to an embodiment, a cathode terminal of the diode D231-2 is coupled, preferably connected, to the node N201, and an anode terminal of the diode D231-2 is coupled, preferably connected, to a terminal of the driving circuit Driv232, for example the drain terminal of the transistor M232-1 described below. The role of the diode D231-2 is described in more detail below. According to one embodiment, the diode D231-2 has its P-type doped well coupled, preferably connected, to the substrate of the driving circuit Driv231.

According to a first preferred embodiment, the diode D231-2 is a parasitic diode of a MOS transistor not shown in FIG. 2, for example an intrinsic diode, also called body diode, or a substrate diode. An example of a structure of a MOS transistor and its parasitic diodes is described in relation to FIG. 3.

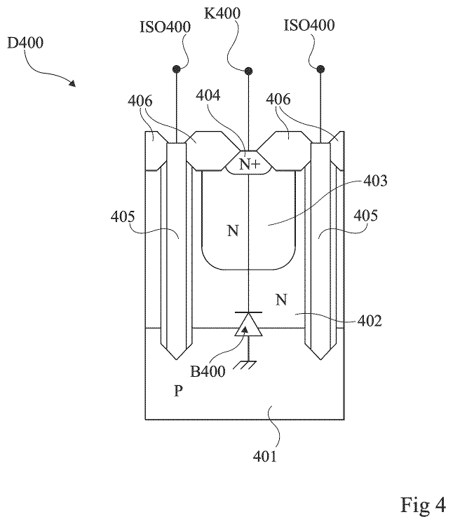

According to a second embodiment, the diode D231-2 is a substrate diode as the one described in relation to FIG. 4.

The circuit GD231 further comprises a second transistor M231-2, a current source CS231-1, and a Zener diode DZ231-1. The transistor M231-2 couples the node N201 to a node N202, in turn coupled, preferably connected, to the gate terminal of the transistor M231-1. More particularly, a source terminal of the transistor M231-2 is coupled, preferably connected, to node N201, and a drain terminal of the transistor M231-2 is coupled, preferably connected, to node N202. A gate terminal of the transistor M231-2 is suitable for receiving a voltage from the level shifter circuit LS231. An output of the current source CS231-1 is coupled, preferably connected, to node N202, and a reference terminal of the current source CS231-1 is coupled, preferably connected, to node N204. The anode of the Zener diode DZ231-1 is coupled, preferably connected, to node N201, and the cathode of the Zener diode DZ231-1 is coupled, preferably connected, to node N202.

The level shifter circuit LS231 is intended to shift the control signals of the Driv232 circuit referenced to the node GND200 and supplied by the potential present at the node VDD200, towards the Driv231 circuit referenced to the node N201 and supplied to lower the voltage supplied by the supply circuit Supp231. The circuit LS231 comprises a level shifter circuit LS231-1 and four NMOS transistors M231-3, M231-4, M231-5, and M231-6.

According to one example, the level shifter circuit LS231-1 is powered with the potential of node N204, and is referenced to node N201. An inverting output of the circuit L231-1 is coupled, preferably connected, to the gate of the transistor M231-3 of the circuit GD231.

According to an example, transistors M231-3 and M231-6 are low voltage transistors, arranged to form a low voltage current mirror circuit. Transistors M231-4, M231-5 are high voltage transistors arranged to form a cascode circuit for protecting the low voltage current mirror from high voltages. More particularly, a source terminal of the transistor M231-3 is coupled, preferably connected, to node N201, and a drain terminal of the transistor M231-3 is coupled, preferably connected, to the source of the transistor M231-4. A drain terminal of the transistor M231-4 is coupled, preferably connected, to the gate terminals of the transistors M231-4 and M231-5, and to the drain terminal of the transistor M231-5. A source terminal of the transistor M231-6 is coupled, preferably connected, to the node N201, and a drain of the transistor M231-6 is coupled, preferably connected, to the gate terminals of the transistors M231-3 and M231-6, and to the source terminal of the transistor M231-5.

The intrinsic diodes of the transistors M231-3, M231-4, M231-5, and M231-6 are all shown, and the substrate diodes of the transistors M231-4 and M231-5 are also shown. More particularly, the transistor M231-4 comprises a substrate diode D231-3 and an intrinsic diode D231-4. Similarly, the transistor M231-5 comprises an intrinsic diode D231-5 and an intrinsic diode D231-6.

The circuit LS231 further comprises a resistor R231-2 coupling the drain terminal of the transistor M231-4 to the driving circuit Driv232.

The power supply circuit Supp231 is adapted to provide a supply voltage from the potential provided by the node N201. For this, the power supply circuit Supp231 comprises a circuit Ref231 providing a reference potential, a hysteresis voltage comparator circuit LS231-2, a high-voltage transistor M231-7 of depleted NMOS type and a supply capacitor C231-1. A first terminal of the capacitor C231-1 is coupled, preferably connected, to the node N204, and a second terminal of the capacitor C231-1 is coupled, preferably connected, to the reference node N201. The charge level of the capacitor C231-1 defines the conduction and non-conduction phases of the transistor M231-7. The operation of the power supply circuit Supp231 is accessible to those skilled in the art.

The circuit Ref231 is supplied by the potential of the node N204 and is referenced to the node N201, and provides a reference potential, for example a reference potential different from the potential provided by the node GND200. The circuit Ref231 provides this reference potential to a first input of the hysteresis voltage comparator circuit LS231-2. A second input (−) of the hysteresis voltage comparator circuit LS231-2 is coupled, preferably connected, to the node N204. The hysteresis voltage comparator circuit is referenced to the node N201, and controls the gate of the transistor M231-7. A source terminal of the transistor M231-7 is coupled, preferably connected, to the node N204, and a drain terminal of the transistor M231-7 is connected to the anode of the thyristor T231. Parasitic diodes of transistor M231-7 are shown in FIG. 2. More particularly, an intrinsic diode D231-7 connecting the source and drain terminals of transistor M231-7 is shown, and a substrate diode D231-8 connecting the drain terminal to node N201 and to the substrate of circuit DRIV231 is shown. In addition, another substrate parasitic diode D231-9 appearing between the drain terminal of transistor M231-7 and node GND200, which is itself connected to the substrate of circuit Driv232.

The driving circuit Driv232 is suitable for driving the thyristor T232. To this end, the driving circuit Driv232 comprises an output terminal coupled, preferably connected, to a gate terminal of the thyristor T232. The driving circuit Driv232 is powered by a node VDD100 providing a DC power supply voltage, and is referenced to the reference node GND100.

The driving circuit Driv232 includes:
a circuit GD232 for controlling the gate of the thyristor T232;
a control circuit VR232 of the level shifter circuit LS231; and
a control circuit MCU230.

The circuit GD232 for controlling the gate of the thyristor T232 is a circuit allowing a control current pulse to be provided to the gate of the thyristor T232. In other words, an output of the circuit GD232 corresponds to the output of the driving circuit Driv232.

The circuit GD232 comprises a NMOS-type transistor M232-1. According to an alternative within the capabilities of those skilled in the art, the transistor M232-1 could be a PMOS-type transistor. A source terminal of the transistor M232-1 is coupled to the gate of the thyristor T232, for example through a resistor R232-1. A drain terminal of the transistor M232-1 is coupled to node N201. A parasitic diode of the transistor M232-1 is shown in FIG. 2. This parasitic diode is an intrinsic diode D232-1, the anode of which is coupled, preferably connected, to the source terminal of the transistor M232-1, and the cathode of which is coupled, preferably connected, to the drain terminal of the transistor M232-1.

According to an embodiment, the circuit GD232 further comprises a diode D232-2 formed in and on the substrate on which the circuit Driv232 is formed. According to an embodiment, a cathode terminal of the diode D232-2 is coupled, preferably connected, to a terminal of the driving circuit Driv231, more particularly, to the drain terminal of the transistor M231-1, and an anode terminal of the diode D232-2 is coupled, preferably connected, to the node GND200. The role of the diode D232-2 is described in more detail below. According to one embodiment, the diode D232-2 has its P-type doped well coupled, preferably connected, to the substrate of the driving circuit Driv232.

According to a first preferred embodiment, the diode D232-2 is a parasitic diode of a MOS transistor not shown in FIG. 2, for example an intrinsic diode, also called body diode, or a substrate diode. An example of a structure of a MOS transistor and its parasitic diodes is described in relation to FIG. 3.

According to a second embodiment, the diode D232-2 is a substrate diode like that described in relation to FIG. 4.

The circuit GD232 further comprises a second transistor M232-2, a current source CS232-1, and a Zener diode DZ232-1. The transistor M232-2 couples the node GND200 to a node N205 in turn coupled, preferably connected, to the gate terminal of the transistor M232-1. More particularly, a source terminal of the transistor M232-2 is coupled, preferably connected, to node GND200, and a drain terminal of the transistor M232-2 is coupled, preferably connected, to node N205. A gate terminal of the transistor M232-2 is suitable for receiving the control potential of node N207. An output of the current source CS232-1 is coupled, preferably connected, to node N205, and a power supply terminal of the current source CS232-1 is coupled, preferably connected, to a node VDD200 receiving a power supply potential. The anode of the Zener diode DZ232-1 is coupled, preferably connected, to node GND200, and the cathode of the Zener diode DZ232-1 is coupled, preferably connected, to node N205.

The control circuit VR232 of the LS231 level shifter circuit makes it possible to generate two complementary control signals from the control signal provided by the MCU230 control circuit. The VR232 circuit comprises two power logic inverters formed by the transistors M232-5, M232-6, and the two transistors M232-3 and M232-4, and a Schmitt flip-flop circuit LS232-1, also known as the “Schmitt Trigger” LS232-1, for interpreting the control signals provided by the MCU230 control circuit.

According to one example, the transistors M232-3, M232-4, M232-5, and M232-6 are arranged so as to form two inverters in cascade used for controlling the level shifter circuit LS231. More particularly, a source terminal of the transistor M232-3 is coupled, preferably connected, to node VDD200, and a drain terminal of the transistor M232-3 is coupled, preferably connected, to the drain of the transistor M232-4. A source terminal of the transistor M232-4 is coupled, preferably connected, to reference node GND200. A source terminal of the transistor M232-6 is coupled, preferably connected, to the node VDD200, and a drain terminal of the transistor M232-6 is coupled, preferably connected, to the drain terminal of the transistor M232-5. A source terminal of the transistor M232-5 is coupled, preferably connected, to the reference node GND200. The gate terminals of the transistors M232-3 and M232-4 are coupled, preferably connected, to each other and to a node N207. This node N207 is further coupled, preferably connected, to the mid-node between the transistors M232-5 and M232-6. The gate terminals of the transistors M232-5 and M232-6 are coupled, preferably connected, to each other, and to an output terminal of the voltage shifter circuit LS232-1. The intrinsic diodes of the transistors M232-3, M232-4, M232-5, and M232-6 are all shown.

The control circuit VR232 further comprises Zener diodes DZ232-2 and DZ232-3 intended for protecting the driving circuit Driv232 against electrostatic discharges. To this end, a cathode terminal of the diode DZ232 is coupled, preferably connected, to a node N206 corresponding to a mid-node between the transistors M232-3 and M232-4. This node N206 is further coupled, preferably connected, to a second terminal of the resistor R232-1 of the circuit LS231. An anode terminal of the diode DZ232-2 is coupled, preferably connected, to the reference node GND200. A cathode terminal of the diode DZ232-3 is coupled, preferably connected, to node N207. An anode terminal of the diode DZ232-3 is coupled, preferably connected, to a node GND200.

An input terminal of the voltage shifter circuit LS232-1 is coupled, preferably connected, to an output of the control circuit MCU230.

The control circuit VR232 further comprises a resistor R232-2 coupling the node 207 to the circuit LS231 of the driving circuit Driv231. More particularly, a first terminal of the resistor R232-2 is coupled, preferably connected, to node N207, and a second terminal of the resistor R232-2 is coupled, preferably connected, to the drain terminal of the transistor M231-5.

The control circuit MCU230 is suitable for providing a control voltage to the transistor M232-1 converting it into a control pulse for the thyristor T232. In practice, the control circuit MCU230 can be a controller, a microcontroller, a processor, and/or a microprocessor.

The control circuit MCU230 could further comprise a supply capacitor C232-1. A first terminal of the capacitor C232-1 is coupled, preferably connected, to node VDD200, and a second terminal of the capacitor C232-1 is coupled, preferably connected, to the reference node GND200.

An advantage of the driving circuits Driv231 and Driv232 is that they have a higher resistance to reverse polarizations. Indeed, the diodes D231-1 and D231-2 make it possible to protect the driving circuits Driv231 and Driv232 against reverse polarities. More particularly, the diode D231-2, which is formed in and on the substrate of the driving circuit Driv231, makes it possible to protect the driving circuit Driv232, and in particular its transistor M232-1, against reverse polarities. Similarly, the diode D232-2, which is formed in and on the substrate of the driving circuit Driv232, makes it possible to protect the driving circuit Driv231, and in particular its transistor M231-1, against reverse polarities. In other words, each driving circuit Driv231, Driv232 is protected against reverse polarities by a diode whose P-box is connected, preferably connected, to the substrate of the other driving circuit Driv232, Driv231. The use of substrate diodes D231-2, D231-9 and D232-2 integrated into the dies of driving circuits Driv231 and Driv232 further allows to avoid the use of non-integrated discrete diodes.

A method for controlling the power supply of the load 210 within the system 200 is as follows. When the load 210 operates, and needs to be powered, the switch 230 is turned ON. To this end, the driving circuits Driv231 and Driv232 send a control current pulse to the thyristors T231 and T232. The thyristors T231 and T232 remain ON as long as a current flows through them. When the load 210 does not operate, and does not need to be powered, the switch 230 is turned OFF. To this end, the thyristors T231 and T232 are turned OFF by sending them no control current pulse.

FIG. 3 is a section view illustrating a practical example embodiment of a N-channel MOS transistor, or NMOS transistor, T300, and illustrating particularly the positioning of its spurious diodes.

As previously stated, FIG. 3 illustrates a NMOS-type transistor T300 comprising spurious diodes, and in particular an intrinsic diode BD300 and a substrate diode SD300. As any MOS-type transistor, the transistor M300 comprises a source terminal S300, a drain terminal D300, a gate terminal G300, and a substrate terminal Sub300.

The transistor T300 is formed in and on a P-type doped substrate 301. A N-type doped well, for example obtained with an epitaxy method, extends over a whole top portion of the substrate 301. The PN junction formed by the substrate 301, and the well 302 forms the substrate diode SD300 of the transistor T300. More particularly, the anode region of the diode SD300 is formed by substrate 301, and the cathode region of the diode SD300 is formed by the well 302.

A N-type doped well 303 intended to receive high voltages is formed within the well 302. This well 303 allows the drain region of the transistor T300 to be formed. A P-type doped well 304 is formed on a portion of the well 303, and extends over a portion of the surface of the well 303. The well 304 allows the channel region of the transistor T300 to be formed. The PN junction formed by the wells 303 and 304 forms the intrinsic diode BD300 of the transistor T300. More particularly, the anode region of the diode BD300 is formed by the substrate 304, and the cathode region of the diode BD300 is formed by the well 303.

A N-type doped well 305 is formed in the well 304. This well 305 allows the source region of the transistor T300 to be formed. A heavily-N-doped source contact region 306 is formed within the well 305. Similarly, a heavily-P-doped source contact region 307 is formed within the well 304.

A gate stack 308 is formed over the channel region 304 and over a portion of the drain region 303 of the transistor T300. And a gate contact is formed on this stack 308. A heavily-N-doped drain contact region 309 is formed within the well 304.

All these contact regions are delimited by an electrically insulating layer 311. In addition, the transistor T300 can be laterally insulated from electrically insulating trenches 310, or by capacitive insulating trenches also usable as substrate contact.

As previously described in relation to FIG. 2, diodes D231-2 and D232-2 may be formed by parasitic diodes of a MOS type transistor. These diodes may therefore be formed, for example, by a substrate diode of the type of diode SD300. According to another example, these diodes may be formed by an intrinsic diode of the type of diode BD300, but in this case the source terminal of the transistor to which the intrinsic diode belongs is connected, preferably connected, to its substrate terminal.

FIG. 4 is a sectional view illustrating a practical example of the embodiment of a D400 diode.

The diode D400 is formed in and on a P-type doped substrate 401 (N). An N-type doped well 402 (N), for example obtained by an epitaxy process, extends over an entire upper portion of the substrate 401. The PN junction formed by the substrate 401 and the well 402 forms the diode D400. More particularly, the anode region of the diode D400 is formed by the substrate 401, and the cathode region of the diode D400 is formed by the well 402.

A contact connection can be formed in the following manner. An N-type doped layer 403 (N) is formed on the upper face of the layer 402, and a heavily N-type doped layer 404 (N+) is formed on a portion of the surface of the layer 403 to form the contact connection. According to one example, the layer 404 is connected, preferably connected, to a node K400 forming the cathode terminal of the diode D400. The remainder of the surface of the layer 403 is, for example, covered with an electrically insulating layer 406.

According to one example, the diode D400 is delimited laterally by a circular electrically insulating trench 310, or by a circular capacitive insulating trench that can also serve as a substrate contact recovery. According to one example, the insulating trench 405 comprises an insulating core, or a core of a heavily doped P-type material, in contact with the substrate 401, and, for example, an electrically insulating contour.

The details of the used materials and of the doping levels of the structures shown in FIG. 3 are not described, and are within the capabilities of those skilled in the art. Similarly, all steps of a method for manufacturing such a transistor or such a diode are within the capabilities of those skilled in the art.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. An electronic device for driving a switch comprising:
a first terminal adapted to receive an alternating potential;
a second terminal adapted to receive a reference potential;
a first driving circuit of the switch referenced to the first terminal, formed on a first substrate, and comprising a first diode whose cathode region is connected to the first substrate;
a second driving circuit referenced to the second terminal formed on a second substrate different from the first substrate, and comprising a second diode whose cathode region is connected to the second substrate; and
wherein an anode region of the first diode is connected to the second driving circuit, and an anode region of the second diode is connected to the first driving circuit.

2. The electronic device for driving the switch of claim 1, wherein the first driving circuit comprises a first transistor for controlling the switch, and the anode region of the second diode is connected to a drain terminal of the first transistor.

3. The electronic device for driving the switch of claim 1, wherein the second driving circuit comprises a second transistor for controlling the switch, and the anode region of the first diode is connected to a drain terminal of the second transistor.

4. The electronic device for driving the switch of claim 2, wherein the second driving circuit comprises a second transistor for controlling the switch, and the anode region of the first diode is connected to a drain terminal of the second transistor, and wherein the first and second transistors are MOS type transistors.

5. The electronic device for driving the switch of claim 1, wherein the first and second diodes are respective parasitic diodes of third MOS type transistors.

6. The electronic device for driving the switch of claim 5, wherein the first and second diodes are respective substrate diodes of the third MOS type transistors.

7. The electronic device for driving the switch of claim 5, wherein the first and second diodes are respective intrinsic diodes of the third MOS type transistors whose source terminals are respectively connected to their substrate terminals.

8. The electronic device for driving the switch of claim 1, wherein the first and second diodes are diodes laterally isolated by deep isolation trenches.

9. The electronic device for driving the switch of claim 1, wherein the first driving circuit comprises a power supply circuit connected to the first terminal.

10. A switch comprising:
the electronic device for driving a switch of claim 1;
a first thyristor whose cathode is connected to the first terminal, and whose anode is connected to the second terminal and adapted to be driven by the first driving circuit; and
a second thyristor whose anode is connected to the first terminal, and whose cathode is connected to the second terminal and adapted to be driven by the second driving circuit.

11. The switch of claim 10, wherein the first driving circuit comprises a first transistor for controlling the switch, and the anode region of the second diode is connected to a drain terminal of the first transistor, and
wherein the first transistor comprises a source terminal connected to a trigger of the first thyristor.

12. The switch of claim 10, wherein the second driving circuit comprises a second transistor for controlling the switch, and the anode region of the first diode is connected to a drain terminal of the second transistor, and wherein the second transistor comprises a source terminal connected to a trigger of the second thyristor.

13. An electronic device comprising a load adapted to receive an alternating voltage and the switch of claim 10, wherein a third terminal of the load is connected to the first terminal.

14. An electronic system comprising the electronic device of claim 13 and a power supply adapted to provide the alternating voltage.

15. A method of controlling a load supplied by a power supply adapted to supply an alternating voltage, in which the load is connected to the power supply by a switch, the switch comprising:
a first terminal adapted to receive an alternating potential;
a second terminal adapted to receive a reference potential;
a first thyristor whose cathode is connected to the first terminal, and whose anode is connected to the second terminal;
a first driving circuit of the switch referenced to the first terminal, formed on a first substrate, and comprising a first diode whose cathode region is connected to the first substrate;
a second driving circuit of a second thyristor referenced to the second terminal formed on a second substrate different from the first substrate, and comprising a second diode whose cathode region is connected to the second substrate; and
wherein an anode region of the first diode is connected to a second driving circuit, and an anode region of the second diode is connected to a first driving circuit.
